(19) United States
(12) Patent Application Publication
(10) Pub. No.: US 2007/0166838 A1
(43) Pub. Date: Jul. 19, 2007

(54) Method for patterning a ferroelectric polymer layer

(75) Inventors: Albert W. Marsman, Eindhoven (NL); Nicolaas Petrus Willard, Eindhoven (NL)

Correspondence Address: PHILIPS ELECTRONICS NORTH AMERICA CORPORATION;INTELLECTUAL PROPERTY & STANDARDS, 1109 MCKAY DRIVE, M/S-41SJ, SAN JOSE, CA, 95131, US

(73) Assignee: KONINKLIJKE PHILIPS ELECTRONICS N.V., EINDHOVEN (NL)

(21) Appl. No.: 10/584,040

(22) PCT Filed: Dec. 7, 2004
(86) PCT No.: PCT/IB04/52688

§ 371 Date: Jun. 21, 2006

(30) Foreign Application Priority Data
Dec. 22, 2003 (EP) 03104886.1

(51) Int. Cl. H01L 21/00

(52) U.S. Cl. 438/3

(57) ABSTRACT

Ferroelectric polymers such as for example copolymers of vinylidenedifluoride (VDF) and trifluoroethylene (TrFE) may be patterned by spincoating the ferroelectric polymer layer from a ferroelectric spincoating solution, which comprises a photosensitive crosslinker, onto a substrate followed by irradiating the ferroelectric polymer layer through a mask and removing the unexposed parts of the ferroelectric polymer layer.

The present invention relates to a method for pattering a ferroelectric polymer layer for use in ferroelectric devices, such as ferroelectric memory elements and other electronic components such as memory elements made in accordance with the method.

Memory technologies can be broadly divided into two categories: volatile and non-volatile memories. Volatile memories, such as SRAM (Static Random Access Memory) and DRAM (Dynamic Random Access Memory), lose their contents when power is removed while non-volatile memories, which are based on ROM (Read Only Memory) technology do not. DRAM, SRAM and other semiconductor memories are widely used for the processing and high-speed storage of information in computers and other devices. In recent years EEPROMs and Flash Memory have been introduced as non-volatile memories that store data as electrical charges in floating-gate electrodes. Non-volatile memories (NVMs) are used in a wide variety of commercial and military electronic devices and equipment, such as e.g. hand-held telephones, radios and digital cameras. The market for these electronic devices continues to demand devices with a lower voltage, lower power consumption and a decreased chip size. EEPROMs and Flash Memory, however, take long time to write data, and have limits on the number of times that data can be rewritten.

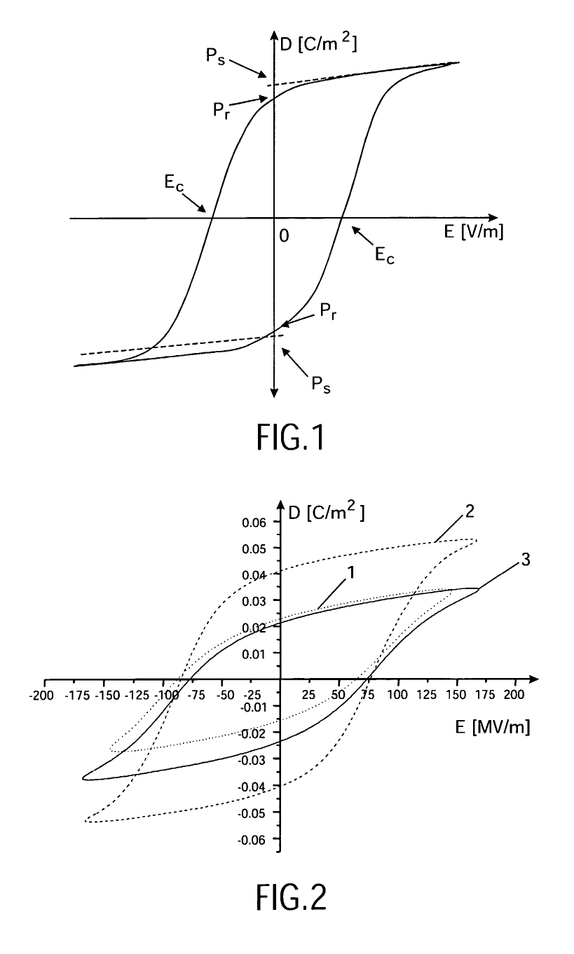

As a way to avoid the shortcomings of the types of memory described above, ferroelectric random access memories (FRAMs), which store data by the electrical polarization of a ferroelectric film, were suggested. A ferroelectric memory cell comprises a ferroelectric capacitor and a transistor. Its construction is similar to the storage cell of a DRAM. The difference is in the dielectric properties of the material between the capacitor's electrodes, which in case of a FRAM is a ferroelectric material. A material is said to be ferroelectric when it features a permanent electric dipole moment, i.e. even without application of an external electric field, that can be switched between at least two states at an electric field lower than the breakdown voltage. In this case, there is more than one stable electric polarization state within the unit cell of its lattice structure. This results in a permittivity of the material being a non-linear function of an applied electric field (E). A plot of the surface-charge density D versus applied field E on a capacitor produces a characteristic hysteresis loop, as is shown schematically in FIG. 1. The positive and negative saturation polarizations (Pₛ) correspond to the binary logic states, e.g. “1” and “0”, of a memory cell, whereas the remnant polarizations (Pᵣ) correspond to the state the cell resides in when the voltage of the power source, or thus the electrical field E, is turned off. Hence, the remnant polarization provides the non-volatility of the memory cell.

The ferroelectric film on the memory cell capacitor may be made of inorganic materials such barium titanate (BaTiO₃), lead zirconate titanate (PZT-Pb(Zr, Ti)O₃)), PLZT ((Pb,La)(Zr,Ti)O₃)) or SBT (SrBi₂Ta₂O₉), or of organic molecular materials such as triglycine sulphate (TGS) or organic oligomers or polymers with polar groups such as e.g. polyvinylidenedifluoride p(VDF) (CH₂—CF₂)ₙ, odd numbered nylons or polyvinylidene cyanide p(VCN). Optimization of these polar layers may be done by the use of (random) copolymers of for example p(VDF) with trifluorethylene TrFE (CHF—CF₂)ₙ or tetrafluoroethylene TFE, (CF₂—CF₂)ₙ or terpolymers or higher order polymeric combinations thereof. In general any material that has a crystalline phase with a crystal structure belonging to an asymmetric space group (asymmetry within the crystalline unit cell) can be used as longs as the electrical breakdown field is higher than the required switching field (related to coercive field) to invert the polarization.

In case of non-volatile memory cells used in polymeric integrated circuits, materials from the latter group, i.e. organic ferroelectric materials, for example as mentioned above, are preferred as a ferroelectric layer with respect to for instance: cost, integration or available temp budget during processing.

The integration of these materials into the devices, however, is not trivial. In general, the materials have excellent solubility in common polar organic solvents. These materials further are hydrophobic and hence, do not like aqueous solutions. Furthermore, the show low adhesion to other device layers. In addition, these materials are rather inert towards chemicals and radiation. Hence, patterning of the ferroelectric layers via standard procedures, such as for example standard photolithography, is hampered. Although in a variety of applications patterning is either not necessary or circumvented by patterning bottom and/or top electrode layers, application in for example, polymer electronics, as an active gate dielectric requires the preparation of for instance via's for contact with source/drain and/or gate layers.

As already mentioned, application of standard lithography for patterning is difficult. This is because the ferroelectric polymer dissolves in the polar organic solvents, which are commonly used to remove photoresist. This results in a complete lift-off of all upper layers, which is of course not desirable in the processing of electronic devices.

In US 2003/0001151 a ferroelectric polymer (FEP) storage or memory device, including a patterned ferroelectric polymer structure that is sandwiched between arrays of electrodes which achieve electrical signaling across the ferroelectric polymer structure, is described. The ferroelectric memory device is fabricated by means of spin-on polymer processing and etching using a photolithographic technology. In the discussed document, patterning of the ferroelectric layer is performed as follows. First, a photoresist is spun onto the ferroelectric layer. The photoresist is then exposed to UV light, for example, and is subsequently patterned to form a mask. Thereafter, an oxygen plasma etch is carried out at a temperature of about 23° C. and a pressure of about one atmosphere. The etch effectively removes the exposed parts of the FEP layer and leaves the non-exposed or mask covered parts in place, resulting in segmented, elongated FEP structures. However, the use of oxygen plasma etching may cause damage to the substrate carrying the FEP, which in case of plastic or polymer integrated circuits is often made of organic layers, or may give rise to implantation of foreign atoms or ions. This is disadvantageous in the processing of electronic or memory devices because it may lead to electrical leakage problems. Furthermore unwanted residual layers may be left at the surface of the substrate carrying the FEP layer in case of incomplete etching.

It would be desirable to have a method for patterning ferroelectric layers, which may be used in for example processing of electronic or memory devices, which is easy, low-cost, and does not have the disadvantages of the method described in US 2003/0001151, and whereby the ferroelectric layer still remains ferroelectric after patterning.

It is an object of the present invention to provide a method for patterning a ferroelectric layer which does not lead to undesired ion production and/or implantation and which preferably at least partly leaves the original ferroelectric properties as well as, preferably the substrate or underlying layers intact.

The above objective is accomplished by a method and device according to the present invention.

The present invention provides a method for patterning a ferroelectric polymer or oligomer layer comprising:

providing a ferroelectric polymer or oligomer composition having a crosslinking agent,

applying the ferroelectric polymer or oligomer composition to a substrate to form a ferroelectric polymer or oligomer layer on the substrate,

selectively cross-linking a part of the ferroelectric polymer or oligomer layer, and

removing uncrosslinked parts of the ferroelectric polymer or oligomer layer.

The ferroelectric polymer layer formed by the method of the present invention may have a remnant polarization Pr>10 mC/m², preferably>50 mC/m² and may for example be ˜100 mC/m². The ferroelectric polymer may preferably be a main chain polymer. However, the ferroelectric polymer may also be a block copolymer or a side chain polymer. The ferroelectric polymer or oligomer may comprise an at least partly fluorinated material. The at least partly fluorinated polymer or oligomer material may be selected from (CH₂—CF₂)ₙ, (CHF—CF₂)ₙ (CF₂—CF₂)ₙ or combinations thereof to form (random) copolymers such as for example: (CH₂—CF₂)ₙ—(CHF—CF₂)ₘ or (CH₂—CF₂)ₙ—(CF₂—CF₂)ₘ.

The step of applying the ferroelectric polymer or oligomer composition onto the substrate may be performed by means of for example dropcasting, doctor blade, lamination of a prefabricated composite film, printing or spincoating.

In embodiments of the invention, the crosslinking agent may be photosensitive, chemical or heat sensitive. The crosslinking agent can be a radiation crosslinking agent. The radiation may be light, e.g. laser light, and the light may have any suitable wavelength, e.g. optical, IR, UV wavelengths. Alternatively, the radiation may be rays or particles such as provided by a low energy electron beam or X-ray beam, provided no or insignificant damage occurs to the ferroelectric polymer. The selective crosslinking may then be performed by exposing a part of the ferroelectric layer to radiation through a mask. Another alternative is to use a crosslinking agent which is triggered by the application of heat that may be delivered through for instance a laser spot.

Furthermore, the crosslinking agent may lead to an electron deficient intermediate, with the restriction that after crosslinking ionic products are minimized. The electron deficient intermediate may for example be a radical, carbene or nitrene intermediate. The crosslinking agent may for example be an azide such as e.g. a bisazide. More specific, the bisazide may for example be 2,6-bis(4-azidebenzylidene)-4-methylcyclohexanone.

In another embodiment, the spincoating solution may furthermore comprise an organic solvent which may for example be dimethylformamide or 2-butanone.

Patterning of a ferroelectric polymer layer may for example be used to form holes in the ferroelectric polymer layer to later provide contact between for example 2 conductive layers, so as to form vias.

The present invention furthermore provides a device comprising a patterned crosslinked ferroelectric layer. The ferroelectric layer may be patterned according to the method of the present invention. In one embodiment, the device may be a capacitor. In another embodiment the electronic device may be a memory element. The crosslinked ferroelectric layer may be radiation crosslinked, chemically crosslinked or heat crosslinked.

An advantage of the present invention is that no dry etching is required to remove the exposed parts of the ferroelectric polymer and hence substantially no damaging of the substrate and no contamination with etch species such as ions or molecules) or gases occurs. Another advantage of the method in the present invention is that it is easy and fast to perform and hence results in a low-cost process.

With the method of the present invention, a device comprising a capacitor which may comprise a ferroelectric dielectric and a transistor which may comprise a non-ferroelectric dielectric can be processed. The ferroelectric dielectric of the capacitor may the be patterned using the method according to the present invention, before the non-ferroelectric dielectric of the transistor may be deposited.

These and other characteristics, features and advantages of the present invention will become apparent from the following detailed description, taken in conjunction with the accompanying drawings, which illustrate, by way of example, the principles of the invention. This description is given for the sake of example only, without limiting the scope of the invention. The reference figures quoted below refer to the attached drawings.

FIG. 1 is a graph illustrating surface charge density D on a ferroelectric capacitor versus applied electric field E.

FIG. 2 is a graph illustrating ferroelectric hysteresis loops before crosslinking and after crosslinking with or without annealing, according to specific embodiments of the present invention.

The present invention will be described with respect to particular embodiments and with reference to certain drawings but the invention is not limited thereto but only by the claims. The drawings described are only schematic and are non-limiting. In the drawings, the size of some of the elements may be exaggerated and not drawn on scale for illustrative purposes. Where the term “comprising” is used in the present description and claims, it does not exclude other elements or steps. Where an indefinite or definite article is used when referring to a singular noun e.g. “a” or “an”, “the”, this includes a plural of that noun unless something else is specifically stated.

Furthermore, the terms first, second, third and the like in the description and in the claims, are used for distinguishing between similar elements and not necessarily for describing a sequential or chronological order. It is to be understood that the terms so used are interchangeable under appropriate circumstances and that the embodiments of the invention described herein are capable of operation in other sequences than described or illustrated herein.

Moreover, the terms top, bottom, over, under and the like in the description and the claims are used for descriptive purposes and not necessarily for describing relative positions. It is to be understood that the terms so used are interchangeable under appropriate circumstances and that the embodiments of the invention described herein are capable of operation in other orientations than described or illustrated herein.

One aspect of the present invention is patterning of ferroelectric polymer layers after crosslinking of the polymer.

As known to the skilled person crosslinking may be achieved in many ways. With reference to the ferroelectric p(VDF) materials only three methods are known. In a first method, crosslinking may be achieved by exposing the polymer, through a mask, to an oxygen plasma as described above or to high energy irradiation, such as for example synchrotron X-ray (2-10 keV, 100 J/cm³), electron beam (3 MeV 5 10⁷ rads), ion beam (1 keV-100 MeV), excimer lasers (ArF—6.4 eV and KrF—5 eV) or UV (2.25-3.96 eV) E. Katan J. Appl. Polym. Sci. 70 1998 1471-1481. However, this approach generally introduces defects into the original polymer leading to deterioration of the ferroelectric effect necessary for memory applications. It is used to fabricate relaxor ferroelectrics having diminished ferroelectric properties, since this treatment converts the ferroelectric phase to the para-electric phase [Q. M. Zhang, Science 280, 1998, 2101-22104]. Besides, the cost of this method even in mass production can be high, and hence is not so suitable to use in processing, for example, memory devices. Nevertheless, patterning has been demonstrated using direct photo etching using aforementioned radiation types [H. M. Manohara et al J. Micromechanical Systems 8(4) 1999 417-422 and J. Choi, Appl. Phys. Lett, 76(3) 2000, 381-383].

A second method comprises crosslinking the polymer through addition of a chemical reagent to the spincoating solution. Although described with reference to a different purpose than patterning and fabrication of a memory, a successful crosslinking attempt has recently been described in literature, R. Casalini et al. Appl. Phys. Lett. 79(16), 2001, pp. 2627-2629 and G. S. Buckley et al. Appl. Phys. Lett. 78(5), 2001, pp. 622-624, and by C. M. Roland and R. Casalini in US 2003/0187143. This method involves heating of a spincoated film consisting of a ferroelectric polymer, peroxide and a radical trap. However, unwanted ionic species are formed as side products from the crosslinking reaction and they remain in the crosslinked network. This is rather undesired since mobile ions or other species in the polymer layer may cause electrical leakage problems as well as deterioration of the ferroelectric effect within the devices produced. Furthermore, heat is difficult to confine, which results in resolution problems where patterning is concerned. Thus, patterning would require photosensitive peroxides, which are not used in the aforementioned prior art.

In a third method the polymer to be crosslinked may contain a suitable base such as for example a bisamine. Since the —CH₂ parts of a VDF unit contain acidic hydrogen atoms, each of these units may react with an amine group to form an imine [D. K. Thomas, J. Appl. Pol. Sci. 8, 1964 1415-1427]. However, for each imine group formation two HF molecules are expelled, which are detrimental for the ferroelectric properties. Similar to the peroxide method, heat activation is necessary which is less suitable for pattern formation through masks.

In the present invention, a crosslinking approach to pattern a ferroelectric polymer, which does not lead to undesired ion production and at least partly leaves the original ferroelectric properties intact, is proposed. Furthermore, the aforementioned defects deteriorating the ferroelectric properties of the polymer are minimized.

In embodiments of the present invention, a ferroelectric polymer layer may be deposited from a solution onto a substrate by means of for example spincoating or silk screen or inkjet printing. The term “substrate” may include any underlying material or materials that may be used, or upon which a device, a circuit or an epitaxial layer may be formed. Furthermore, the “substrate” may include a semiconductor substrate such as e.g. a doped silicon, a gallium arsenide (GaAs), a gallium arsenide phosphide (GaAsP), an indium phosphide (InP), a germanium (Ge), or a silicon germanium (SiGe) substrate. The “substrate” may include for example, an insulating layer such as a SiO₂ or an Si₃N₄ layer in addition to a semiconductor substrate portion. Thus, the term substrate also includes silicon-on-glass, silicon-on sapphire substrates. The term “substrate” is thus used to define generally the elements for layers that underlie a layer or portions of interest. Also, the “substrate” may be any other base on which a layer is formed, for example a glass, plastic or metal layer.

Therefore, first a radiation cross-linkable insulating polymer is applied to a substrate, e.g. by preparing a solution comprising, according to an embodiment of the present invention, a ferroelectric polymer and a crosslinker and then applying the layer by spin coating. Other methods may be used to apply the layer, e.g. a printing technique such as inkjet printing or silk screen printing. Furthermore, any commonly used procedure for the application of polymer layers onto a substrate may be used such as for example dropcasting, doctor blade, lamination of a prefabricated composite film, etc. Optionally, the polymer solution may comprise a solvent, which may for example be 2-butanone or dimethylformamide.

The ferroelectric polymer may for example be based on polyolefins with fluorine atoms (e.g. random copolymers of vinylidenedifluoride (VDF), with trifluoroethylene (TrFE) or with chlorotrifluoroethylene and other fluorinated polymers. However, other ferroelectric polymers, such as for example nylons, cyanopolymers (polyacrylonitriles), poly(vinylidene cyanide) and polymers with a cyano group in the side chain), polyureas, polythioureas and polyurethanes, may also be used.

Furthermore, ferroelectric liquid crystal polymers may be used in for example display or storage applications. However, the remnant polarization Pᵣ of these materials is generally low (˜5-10 mC/m²), being dependent on a dipole moment from a large molecule. This may be too low for memory applications. In addition, operating conditions will be very temperature sensitive due to the liquid crystal properties.

For memory application one likes to have stable properties at temperatures in between approximately −20 to 150 degree C. Furthermore, it is important that the remnant polarization Pᵣ of the ferroelectric polymer is as high as possible. Hence, materials having a high density of large dipole groups are preferred such as is the case in fluorine containing polymers, which have a remnant polarization>10 mC/m², preferably>50 mC/m², and may for example be ˜100 mC/m². The upper limit may be determined by the exact application. For example, a 1T-1C (one transistor, one capacitor) device requires the highest Pᵣ possible in order to generate sufficient charge during the destructive reading. For a ferroelectric transistor structure, the Pᵣ determines the countercharge in the transistor channel to be held by the semiconductor. Hence, the semiconductor properties may be important. The Pᵣ does not necessarily have to be as high as possible, but it is preferably so high as to induce sufficient difference in Vₜ and I_{sd} to obtain a good memory window.

Another important reason for Pᵣ not to be too low is that the stability of the stored states (polarizations) will be at least partly dependent on it. In this respect also the coercive field is important. A too high E_{c} results in high switching voltages (generally 2×E_{c}×layer thickness for polarization saturation). However, a too low E_{c} may result in manifestation of detrimental polarization fields within the capacitors when connected to other circuitry having parasitic capacitance.

Thus, although other polymers or molecules exist, the fluorine containing materials seem to have the most beneficial properties. The fluorinated polymer may preferably be a main chain polymer. However, the fluorinated polymer may also be a block copolymer or a side chain polymer. The fluorinated polymer may for example be (CH₂—CF₂)ₙ, (CHF—CF₂)ₙ(CF₂—CF₂)ₙ or combinations thereof to form (random) copolymers such as for example: (CH₂—CF₂)ₙ—(CHF—CF₂)ₘ or (CH₂—CF₂)ₙ—(CF₂—CF₂)ₘ. A problem is that these polymers are rather inert towards both radiation and chemicals. Thus, when pure main chain fluorinated polymers, which may be cheaply obtained from chemical companies, are to be used, crosslinking should be done with highly reactive (crosslinking) reagents.

The crosslinker may form a reactive electron deficient intermediate with the restriction that after crosslinking ionic (side) products are minimized. Electron deficient intermediates may for example be radical, nitrene or carbene intermediates. Whereas the radical intermediate has an unpaired electron and is capable of initiating radical polymerization or crosslinking, the carbene and nitrene intermediates are not strictly radicals. That is, in triplet state they are biradicals, but in their common singlet state the two free electrons are paired. Such species with paired electrons can insert into single bonds. That is a very attractive feature, since that will not leave reaction products other than those accompanying the formation of the reactive carbenes or nitrenes. The crosslinker may for example be a photosensitive or a heat sensitive crosslinker. A specific example of a crosslinker that may be used in this invention is an azide such as for example a bisazide (e.g. 2,6-bis(4-azidebenzylidene)-4-methylcyclohexanone) or a diazoquinone. Other possible crosslinkers that may be used in the present invention may be azo compounds such as for example 1,1′-azobis(cyclohexanecarbonitrile), 2,2′-azobisisobutymitrile (both radical initiators and only heat sensitive), or azide compounds such as for example 4-4-dithiobisphenyl-azide, 3,3′-diazododiphenyl sulphone (both are heat sensitive and deep UV sensitive<300 nm) or diazo compounds (2,3-bis-diazomethyl-6-phenyl-2,3,3A,6-tetrahydro-1H-indene, N,N′-4,4′-bisphenylylene bis(6-diazo-5,6-dihydro-5-oxo-1-naphthalene sulfonamide (both are heat sensitive and photosensitive).

Secondly, although the crosslinking reagents should preferably be rather reactive, it is important that they do not leave any or a significant amount of side products as contaminants such that these would seriously degrade device operation since ions can compensate charge within the ferroelectric layer. Therefore, as mentioned above, crosslinkers that do not leave significant ionic contamination, are proposed in this invention. It is to be noted that peroxide, which is a radical crosslinker, is preferably not used in this invention, because it has been shown to give rise to ionic contamination.

After spincoating, a mask is applied to the ferroelectric polymer layer. The mask may be formed by for example deposition of a photoresist layer onto the ferroelectric polymer layer by means of spin coating for example, followed by irradiation and patterning of the photoresist. The photoresist layer may for example be made of any suitable polymer that can be used as a photoresist, such as for example poly(vinyl cinnamate) or novolak-based polymers.

Alternatively, contact exposure of the spincoating mixture through a prefabricated mask such as for instance a reticule will also work. Then, no resist step has to be performed. The unexposed parts can be directly removed with suitable procedure such as for example dissolving in acetone.

The ferroelectric polymer layer is then irradiated through the mask with suitable radiation energy, for example, UV light. Illumination of the exposed parts of the ferroelectric polymer results in a crosslinked polymer network and hence in an insoluble layer. The mask, if defined by a patterned photoresist layer, can either be removed before or after the unexposed parts of the ferroelectric layer are removed, depending on the resist that has been used, removing the mask after the unexposed parts are removed may be done by for example stripping. The unwanted and hence unexposed parts of the polymer layer, which are not crosslinked, may subsequently be removed by washing with for example acetone, thus leaving a patterned film of ferroelectric polymer material. The patterned crosslinked ferroelectric polymer layer may be annealed at for instance 140° C. during 2 hours to increase the ferroelectric properties, e.g. to increase the remnant polarization Pᵣ to a level higher than ˜20 mC/m².

An advantage of the method of the present invention is that, with respect to standard photolithography, no additional process steps are required. This reduces processing time and hence results in a low-cost manufacturing method for devices, which need in any way a patterned ferroelectric polymer layer. By applying the method of the present invention, i.e. adding a suitable crosslinker to the spincoating solution, it becomes possible to pattern ferroelectric polymer layers without having any of the disadvantages of methods described in the prior art.

Furthermore, in the crosslinked polymer according to the present invention, crystalline parts from the original, not crosslinked polymer are found in the crosslinked polymer. It may hence be concluded that after spincoating, the layer has a structure which comprises small parts of crystalline fluorinated polymer material embedded in an amorphous matrix consisting of the same polymer and crosslinking agent. Exposure will thus lead to crosslinking in the amorphous parts while the crystalline parts remain unaltered. Hence, those parts of the polymer that make the device switch remain free of crosslinks, which is very important for the devices formed according to the present invention. Therefore, the method according to the present invention is particularly suitable for use in electronic devices such as for example capacitors, memory elements and other devices requiring the active ferroelectric layer. This is an advantage with respect to PDLC (poly dispersed liquid crystal) used in displays. PDLC comprises two parts, a base polymer, which is a polymer matrix and a ferroelectric part, which is a particular molecule. Hence, in case of PDLC the ferroelectric part concerns a complete molecule, while in case of the present invention, the ferroelectric part can be part of a polymer and not a complete molecule. Therefore, after crosslinking, PDLC is substantially fixed and hence has a low dipole moment. The smaller the dipole moment, the lower the remanent polarization and hence, because of that low dipole moment, PDLC has a low remanent polarization and hence, is not suitable for use in electronic devices.

In a specific embodiment of the present invention, the method for patterning ferroelectric polymer layers as described in the first embodiment, is applied to the processing of a capacitor. This embodiment is given as an example only, and the method of the present invention is not limited to the processing of capacitors.

A ferroelectric polymer layer is spincoated onto a substrate from a solution comprising ferroelectric polymer material and a photosensitive crosslinking agent. The solution may for example comprise a mixture of 2.01 g TrFe (50%) NDF (50%) copolymer (other percentage ratio's of VDF and TrFE may be used), 0.20 g 2,6-bis(4-azidebenzylidene)-4-methylcyclohexanone and 49.51 g 2-butanon. The substrate may for example be a glass, semiconductor, conductive polymer or any other suitable conductive substrate, and may contain indium tin oxide (ITO) electrodes as the first electrode of the capacitor. The substrate may be cleaned by for example a standard Annemas cleaning procedure. The Annemas cleaning procedure includes cleaning in a ultrasonic cleaning bath filled with strong alkaline detergent solution, followed by rinsing in water, followed by rinsing in isopropyl alcohol and drying with isopropyl alcohol vapour. As a very strong alkaline soap is used, the annemas cleaning procedure may only be used to clean glass substrates and glass provided with.

During the spincoating process, the substrate may for example be rotated at 2000 rpm during 20 seconds followed by rotation at 500 rpm for 30 seconds. Subsequently the deposited ferroelectric polymer layer may be dried at, for example, 60° C. for 60 seconds. The above described procedure results in a ferroelectric polymer layer with a thickness between 200 and 250 nm being deposited on the substrate. Other thicknesses may be obtained under different circumstances as required. To enhance the adhesion of the ferroelectric polymer onto the substrate, the Annamas cleaned substrates may be treated with an aminosilane adhesion promoter. However, this step is optional and depends on the kind of substrate used.

The polymer layer may then be exposed to light with a wavelength corresponding to the absorption wavelength of the photosensitvie crosslinker, e.g. to light with a wavelength of 365 nm (which is the absorption wavelength of a bisazide), light in N₂ atmosphere. The nitrogen atmosphere is preferred, but because to increase the efficacy of the crosslinker, an oxygen and water free environment may be used, any other atmosphere may be used provided that it is oxygen and water free. Exposure to light may be done through a mask which has a pattern identical to the ITO electrode pattern, being the first electrode of the capacitor. Exposure in air is not possible because crosslinking of thin ferroelectric polymer layers is suppressed by oxygen, which is present in air. The mask is applied onto to the ferroelectric polymer layer as described in the first embodiment of the present invention. During exposure, in the example given, azide groups undergo sequential loss of molecular nitrogen. Each fragmentation produces a nitrene. Nitrene is a highly reactive, electron deficient intermediate. Crosslinking may be achieved by the nitrene intermediates inserting into carbon-hydrogen or carbon-carbon single bonds, converting the polymer into an insoluble network. The exposed parts of the ferroelectric polymer layer may then be developed by for example acetone spraying. In that way, the unexposed parts of the ferroelectric polymer layer may be dissolved, resulting in a patterned ferroelectric polymer layer.

In a last step the patterned ferroelectric polymer layer may be annealed to enhance the ferroelectric properties. Ferroelectric hysteresis loops may be measured with for example a Sawyer-Tower setup at 10 Hz sinusoidal voltage. The ferroelectric hysteresis loops, before crosslinking (graph 1 in FIG. 2) and after crosslinking (graphs 2 and 3 in FIG. 2) are compared in FIG. 2. In the latter case, hysteresis loops both with annealing (graph 2 in FIG. 2) and without annealing (graph 3 in FIG. 2) are shown. From FIG. 2 it is clear that annealing almost doubles the remnant polarization Pᵣ, which corresponds to the state the memory cell resides in when the voltage of the power source is turned off.

Subsequently, a conductive layer, which may for example be a metal (such as e.g. aluminum, gold, copper . . . ), a conductive polymer, or any other suitable conductive material, may be evaporated on top of the ferroelectric polymer pattern as the second electrode layer to form the capacitor.

By using the method of the present invention for patterning ferroelectric polymers it is thus possible to process fully patterned stacks comprising ferroelectric gate isolator layers.

It is to be understood that although preferred embodiments, specific constructions and configurations, as well as materials, have been discussed herein for devices according to the present invention, various changes or modifications in form and detail may be made without departing from the scope and spirit of this invention.

Ferroelectric polymers such as for example copolymers of vinylidenedifluoride (VDF) and trifluoroethylene (TrFE) may be patterned by spincoating the ferroelectric polymer layer from a ferroelectric spincoating solution, which comprises a photosensitive crosslinker, onto a substrate followed by irradiating the ferroelectric polymer layer through a mask and removing the unexposed parts of the ferroelectric polymer layer.

1. A method for patterning a ferroelectric polymer or oligomer layer comprising the steps of:
providing a ferroelectric polymer or oligomer composition having a crosslinking agent,
applying the ferroelectric polymer or oligomer composition to a substrate to form a ferroelectric polymer or oligomer layer on the substrate,
selectively crosslinking a part of said ferroelectric polymer or oligomer layer, and
removing uncrosslinked parts of said ferroelectric polymer or oligomer layer.

2. A method according to claim 1, wherein the ferroelectric polymer or oligomer is a main chain polymer, a block copolymer or a side chain polymer.

3. A method according to claim 1, wherein the ferroelectric polymer or oligomer layer comprises an at least partly fluorinated material.

4. A method according to claim 3, wherein the at least partly fluorinated polymer or oligomer material is selected from: (CH₂—CF₂)ₙ, (CHF—CF₂)ₙ(CF₂—CF₂)ₙ or combinations thereof to form (random) copolymers such as for example: (CH₂—CF₂)ₙ—(CHF—CF₂)ₘ or (CH₂—CF₂)ₙ—(CF₂—CF₂)ₘ.

5. A method according to claim 1, wherein said crosslinking agent leads to an electron deficient intermediate.

6. A method according to claim 5, wherein said electron deficient intermediate is a radical, a carbene or a nitrene intermediate.

7. A method according to claim 5, wherein the crosslinking agent is a bisazide.

8. A method according to claim 1, wherein the spincoating solution furthermore comprises an organic solvent.

9. A method according to claim 8, wherein the organic solvent is 2-butanone.

10. An electronic device comprising a patterned crosslinked ferroelectric layer.

11. The electronic device according to claim 10, wherein the electronic device is a capacitor.

12. The electronic device according to claim 10, wherein the electronic device is a memory element.

13. The electronic device according to claim 10, wherein the crosslinked ferroelectric layer is a radiation crosslinked, chemically crosslinked or heat activated crosslinked layer.
